(19) United States
(12) Patent Application Publication
(10) Pub. No.: US 2015/0036836 A1
(43) Pub. Date: Feb. 5, 2015

(54) Mobile Device Headset Interface Module

(71) Applicant: Damon Moon, Santa Clara, CA (US)

(72) Inventor: Damon Moon, Santa Clara, CA (US)

(21) Appl. No.: 13/959,456

(22) Filed: Aug. 5, 2013

(51) Int. Cl. H04R 3/00; H03G 3/02; H04R 1/10

(52) U.S. Cl. CPC H04R 3/00; H04R 1/1033; H04R 1/1016; H04R 1/1008; H03G 3/02; H04R 2430/01
USPC 381/74

(57) ABSTRACT

Various embodiments of a novel mobile device headset interface module are disclosed. In one embodiment, the novel mobile device headset interface module has a roll-slip edge guard with a ridge at each edge endpoint. The ridge forms an elevated wall at each edge endpoint, which prevents slippage of an electrical wire that is rolled around outer surfaces of the mobile device headset interface module. The novel mobile device headset interface module may also include an upward-slope headset input port on a top surface of the mobile device headset interface module to reduce chances of impact-related damages or electrical disconnections to a headset input jack. Furthermore, in one embodiment of the invention, the novel mobile device headset interface module may also include a mute button, a length-adjustable wire roll extender attached with the roll-slip edge guard, extender position-securing holes, a headset-securing clip, and/or a detachable belt strap.

### FIELD OF THE INVENTION

The present invention generally relates to an electronic device. More specifically, various embodiments of the invention relate to a headset interface module that operatively connects a mobile device and a headset unit. In particular, at least some embodiments of the present invention relate to a headset interface module with novel and unique structural and/or functional characteristics.

### BACKGROUND OF THE INVENTION

Mobile electronic devices are increasingly performing a multiple number of functions and tasks as a converged “smart” device, as previously-discrete electronic devices are merged into a single integrated device. For example, a conventional portable music player unit in the past decade is turning into a multifunctional “smart device” that is able to perform conventional music player tasks as well as various wireless communications and computing functions. An MP3-file music player that also connects to the Internet via a WiFi transceiver to play video files on its display screen is an example of a converged “smart” device. Furthermore, “smart phones” today merge cellular handset functions, music player functions, Internet-enabled wireless router functions (i.e. “wireless hotspots”) for laptop computers and other computing devices, and computer software application execution functions with a wide variety of mobile applications available in an Internet portal site.

As the digital convergence brings smart devices with multiple functions, including the cellular communication functions and the music player functions, advancement in near-distance wireless communication by various versions of Bluetooth and other personal-area networks protocols (i.e. IEEE 802.15) enabled wireless headsets, earbuds, and other wireless accessories to effectively communicate with a mobile device without physical cords or jack connections. For instance, a Bluetooth stereo headset with an embedded microphone in today's consumer electronics market functions as a music headset as well as a cellular “hands-free” headset.

However, wireless headsets typically require an active circuitry with a battery or another power source, unlike corded headsets. For many consumers, the inconvenience of frequent battery-charging requirements on wireless headsets and the degradation of headset batteries for shorter operational life per charging cycle over time are substantial drawbacks that prevent adaptation of wireless headsets. Moreover, corded headsets are often included in an original mobile device package box, unlike wireless headsets which cost extra at electronic accessory shops.

Unfortunately, significant innovative advancements on corded headsets and related accessory have been deemphasized and have largely remained stale in recent years due to the overemphasis on Bluetooth headsets and wireless accessories. In particular, a common drawback of corded headsets that remains unresolved is frequent tangling of electrical wires among a mobile device jack, input and output jacks for a headset interface module (e.g. a wired remote controller), and a headset unit itself.

For example, a user carrying a mobile device with a corded headset and a headset interface module often finds the interconnecting electrical wires all tangled up in storage or in operation. Furthermore, a corded headset plugged into a headset interface module often gets its input jack damaged or warped, if the user accidentally places one side of the headset interface module flat against a tabletop or another hard object while the input jack is plugged in.

Therefore, it may be advantageous to provide a novel mobile device headset interface module that reduces or eliminates tangling of interconnecting electrical wires. Moreover, it may also be advantageous to provide a novel mobile device headset interface module that is easily attachable and detachable to a main body of a mobile device. In addition, it may also be advantageous to provide a novel mobile device headset interface module that reduces or eliminates the chances of input jack damages. Furthermore, it may also be advantageous to provide a novel mobile device headset interface module that also incorporates a call and/or sound mute button for additional convenience to the user during operation of a mobile device.

### SUMMARY

Summary and Abstract summarize some aspects of the present invention. Simplifications or omissions may have been made to avoid obscuring the purpose of the Summary or the Abstract. These simplifications or omissions are not intended to limit the scope of the present invention.

In one embodiment of the invention, a mobile device headset interface module is disclosed. This mobile device headset interface module comprises: a roll-slip edge guard with one or more ridges at each edge endpoint of the mobile device headset interface module, wherein each ridge forms an elevated wall at each edge endpoint to prevent slippage of an electrical wire that is rolled around outer surfaces of the mobile device headset interface module; an upward-slope headset input port located on a top surface of the mobile device headset interface module, wherein the upward-slope headset input port is configured to dock with a headset input jack of a headset unit at a non-perpendicular angle, which reduces chances of impact-related damages or undesirable electrical disconnections to the headset input jack and the mobile device headset interface module; and a mute button located on the top surface of the mobile device headset interface module, wherein the mute button blocks or mutes sound signals originating from a mobile device or from the headset unit, which is operatively connected to the mobile device headset interface module.

In another embodiment of the invention, another mobile device headset interface module is disclosed. This mobile device headset interface module comprises: a first roll-slip edge guard with a first set of ridges at edge endpoints of a first edge of the mobile device headset interface module; a second roll-slip edge guard with a second set of ridges at edge endpoints of a second edge of the mobile device headset interface module, wherein each ridge forms an elevated wall at each edge endpoint to prevent slippage of an electrical wire that is rolled around outer surfaces of the mobile device headset interface module, and wherein the first edge and the second edge are opposite to each other; an upward-slope headset input port located on a top surface of the mobile device headset interface module, wherein the upward-slope headset input port is configured to dock with a headset input jack of a headset unit at a non-perpendicular angle, which reduces chances of impact-related damages or undesirable electrical disconnections to the headset input jack and the mobile device headset interface module; and a mute button located on the top surface of the mobile device headset interface module, wherein the mute button blocks or mutes sound signals originating from a mobile device or from the headset unit, which is operatively connected to the mobile device headset interface module.

### BRIEF DESCRIPTION OF DRAWINGS

FIG. 1 shows a frontal perspective view of a mobile device headset interface module, which is operatively connected to a mobile device and a headset unit, in accordance with an embodiment of the invention.

FIG. 2 shows a top view of a mobile device headset interface module with a mute button and an upward-slope headset input port on a top surface of the mobile device headset interface module, in accordance with an embodiment of the invention.

FIG. 3 shows a perspective view of a mobile device headset interface module with a length-adjustable wire roll extender and extender position-securing holes, in accordance with an embodiment of the invention.

FIG. 4 shows a perspective view of a mobile device headset interface module with a length-adjustable wire roll extender, extender position-securing holes, and a headset-securing clip, in accordance with an embodiment of the invention.

FIG. 5 shows a side view of a mobile device headset interface module with a length-adjustable wire roll extender, extender position-securing holes, and a headset-securing clip, in accordance with an embodiment of the invention.

FIG. 6 shows a perspective view of a mobile device headset interface module attached to a body of a mobile device using detachable belt straps, in accordance with an embodiment of the invention.

FIG. 7 show a perspective view of a mobile device headset interface module attached to a user's hand using detachable belt straps, in accordance with an embodiment of the invention.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

The detailed description is presented largely in terms of procedures, logic blocks, processing, and/or other symbolic representations that directly or indirectly resemble a mobile device headset interface module. These process descriptions and representations are the means used by those experienced or skilled in the art to most effectively convey the substance of their work to others skilled in the art.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment. Furthermore, separate or alternative embodiments are not necessarily mutually exclusive of other embodiments. Moreover, the order of blocks in process flowcharts or diagrams representing one or more embodiments of the invention do not inherently indicate any particular order nor imply any limitations in the invention.

In general, embodiments of the invention relate to one or more mobile device headset interface modules, each of which is interposed between a mobile device and a headset unit, and provides one or more desirable features based on functional and/or structural uniqueness. Embodiments of the invention also relate to “roll-slip edge guard,” which enables electrical wires to be rolled around an axis of a mobile device headset interface module while preventing slippage of rolled electrical wires from the mobile device headset interface module. In addition, embodiments of the invention also relate to a mute button and an upward-slope headset input port on a top surface of a mobile device headset interface module.

Furthermore, embodiments of the invention also relate to a length-adjustable wire roll extender, extender position-securing holes, and/or a headset-securing clip for a mobile device headset interface module. Moreover, embodiments of the invention also relate to detachable belt straps on a mobile device headset interface module for strapping the mobile device headset interface module onto a mobile device or a user's hand.

For the purpose of describing the invention, a term “mobile device” is defined as a portable electronic device that is at least able to provide sound signals to a headset unit which is either directly or indirectly connected to the portable electronic device. Examples of mobile devices include, but are not limited to, portable music players, cellular phones, smart phones, tablet computers, and notebook computers.

Moreover, a term “mobile device headset interface module” is defined as an electronic remote controller for a mobile device and a headset unit. For example, a mobile device headset interface module may be connected to a mobile device and a headset unit by electrical wires, and include a mute button and input and/or output jacks for the mobile device and the headset unit.

In addition, for the purpose of describing the invention, a term “electrical wire” is defined as an electrically-conductive cable or an electrically-conductive cord, which is generally encapsulated by rubber, polyvinyl chloride (PVC), or another electrically-insulating material at the outer surface of the electrically-conductive cable or the electrically-conductive cord. Furthermore, the electrical wire generally has an input and/or output connect jack at each end of the electrical wire for transmission of electrical signals between one end to the other end of the electrical wire.

Furthermore, for the purpose of describing the invention, a term “headset unit” is defined as a headphone unit, an earbud unit, or another sound-reproducing unit designed to generate sound based on an audio output signal from an electronic device which is either directly or indirectly connected to the headphone unit, the earbud unit, or another sound-reproducing unit. In one example, the headset unit is electrically connected to a mobile device headset interface module via a first electrical wire, wherein the mobile device headset interface module is configured to control sound volume, mute activation or deactivation, or another feature related to a mobile device, which is also electrically connected to the mobile device headset interface module via a second electrical wire.

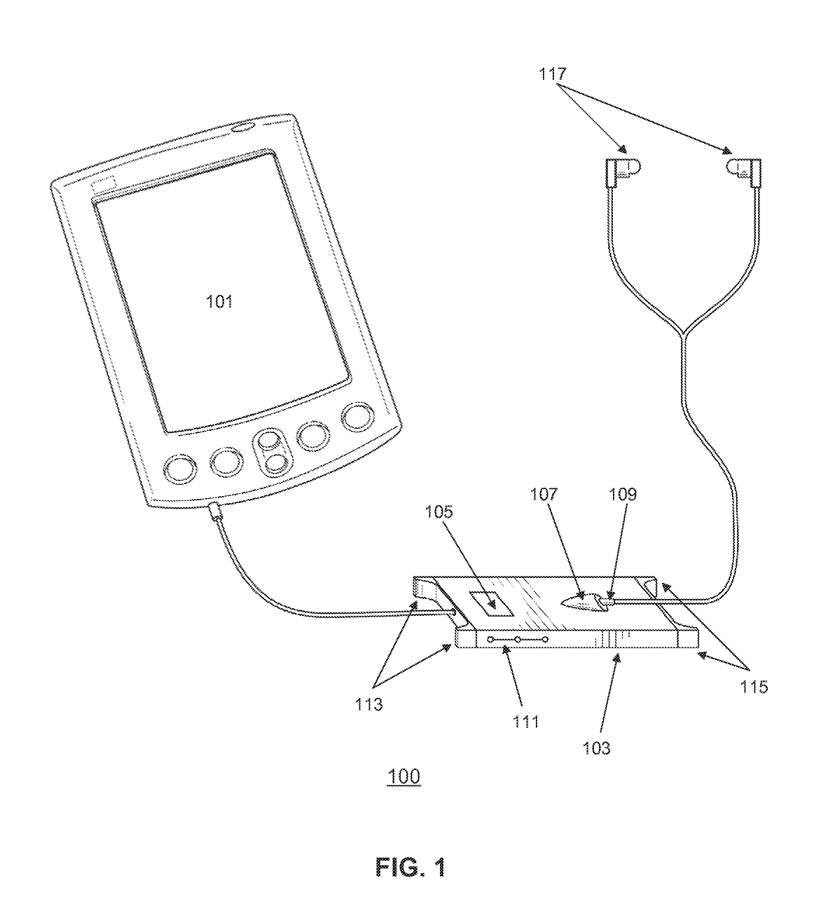

FIG. 1 shows a frontal perspective view (100) of a mobile device headset interface module (103), which is operatively connected to a mobile device (101) and a headset unit (117), in accordance with an embodiment of the invention. In a preferred embodiment of the invention, the mobile device headset interface module (103) comprises a mute button (105) on a top surface, an upward-slop headset input port (107) on the top surface, a first roll-slip edge guard (113), a second roll-slip edge guard (115), and extender position-securing holes (111).

As shown in FIG. 1, in the preferred embodiment of the invention, the mute button (105) is capable of blocking or muting sound signals that originate from a sound output port of the mobile device (101), so that a headset unit (117) connected to the mobile device headset interface module (103) does not receive any sound through speakers in the headset unit (117). In one embodiment of the invention, the mute button (105) may physically block or mute the sound transmission to the headset unit (117). In another embodiment of the invention, the activation of the mute button (105) may trigger a software-based mute command function in a device software operating in the mobile device (101). Examples of sound output ports on the mobile device (101), include, but are not limited to, an analog sound output port that outputs audio signals as analog signals, a digital sound output port that outputs digitally-encoded audio signals, which require digital decoding inside the mobile device headset interface module (103), or an optical sound output port that outputs optically-encoded audio signals, which require optical decoding inside the mobile device headset interface module (103).

Alternatively, the mute button (105) can be utilized to mute or deactivate a microphone that may be embedded in the headset unit (117) or in the mobile device headset interface module (103), so that a user on a telephone call does not transmit any sound through the microphone as long as the mute button (105) is activated. Preferably, by pressing the mute button (105) again, the user can also deactivate the mute feature, whether the mute feature was initially activated to mute sound signals from the sound output port of the mobile device (101), or initially activated to mute the microphone in the headset unit (117) or in the mobile device headset interface module (103).

Continuing with FIG. 1, the upward-slope headset input port (107) is located on the top surface of the mobile device headset interface module (103) in the preferred embodiment of the invention. The upward-slope headset input port (107) has a uniquely-slanted upward angle for docking with a headset input jack (109), which reduces chances of impact-related damages to the headset input jack (109) and the mobile device headset interface module (103). For example, a conventional headset input port forms a perpendicular angle when it is docking with a typical headset input jack of a typical headset unit. If a user drops or persistently brushes the headset input jack against another solid object while the headset input jack is perpendicularly plugged into the conventional headset input port, the perpendicularity of the headset input jack to the conventional headset input port often amplifies or exacerbates impact or stress energy to the headset input jack and the conventional headset input port, thereby causing substantial damages, undesirable electrical disconnection, or operational malfunctions to these devices. In contrast, in the preferred embodiment of the invention, the uniquely-slanted upward angle of the upward-slope headset input port (107) on the top surface of the mobile device headset interface module (103) can substantially reduce impact energy transmitted to the headset input jack (109) and the upward-slope headset input port (107) if these devices experience significant physical shock or impact by a user's accidental mishandling of the mobile device (101), the mobile device headset interface module (103), and/or the headset unit (117).

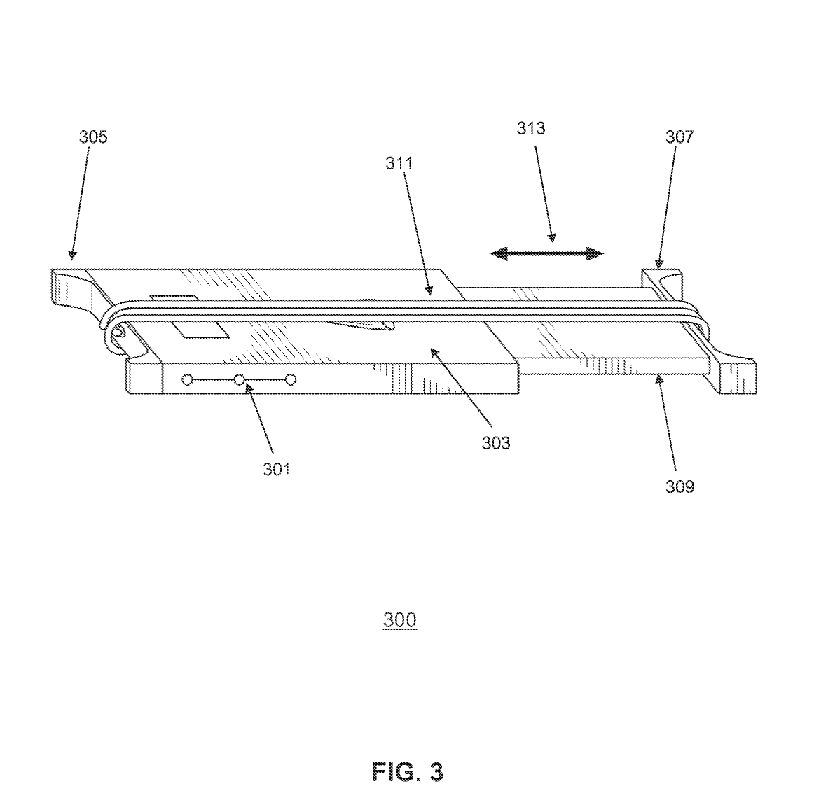

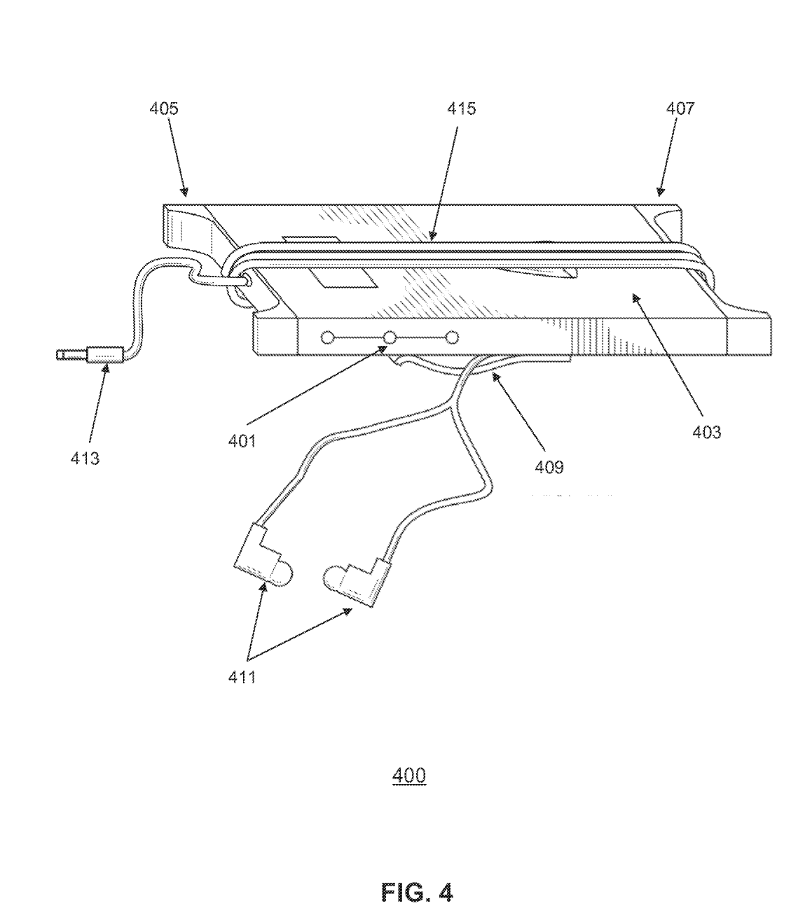

Furthermore, as shown in FIG. 1, the first roll-slip edge guard (113) and the second roll-slip edge guard (115) are located at opposite edges of the mobile device headset interface module (103). In the preferred embodiment of the invention, each edge endpoint, which is at each corner of each edge, has a ridge that forms an elevated wall to prevent slippage of an electrical wire, if the electrical wire is rolled around outer surfaces of the mobile device headset interface module (103). Preferably, each of the first roll-slip edge guard (113) and the second roll-slip edge guard (115) forms a U-shaped structure with a first ridge on one edge endpoint and a second ridge on the other edge endpoint. The ridge prevents a rolled electrical wire from slipping away from the mobile device headset interface module, as shown more clearly in FIG. 3 and FIG. 4.

Continuing with FIG. 1, in one embodiment of the invention, the mobile device headset interface module (103) also has a unique length-adjustable wire roll extender that can extend from or retracts to an edge of the mobile device headset interface module (103). In one example, the length-adjustable wire roll extender can slide in and out of the edge of the mobile device headset interface module, and attach a roll-slip edge guard (e.g. 115) at its exposed edge. Furthermore, this length-adjustable wire roll extender can be used to control or adjust roll termination point for earbuds or headphones as the electrical wire that connects between the mobile device headset interface module (103) and the headset unit (117) is rolled around a length axis of the mobile device headset interface module (103), as shown more in detail in FIG. 3 and FIG. 4. For example, if the earbuds terminate its multi-loop roll at an awkward position after the electrical wire that connects the headset unit (117) and the mobile device headset interface module (103) is rolled around the length axis of the mobile device headset interface module (103), then the user may want to extend the length of the mobile device headset interface module (103) by a few inches to ensure that the roll termination point for the earbuds is within the range of a headset-securing clip (e.g. 409 of FIG. 4).

In one embodiment of the invention, an extended position of the length-adjustable wire roll extender can be securely fixed by using a tooth from a side of the length-adjustable wire roll extender, which snaps into one of the extender position-securing holes (111). The user can change or adjust the extended position by pressing the tooth to dislocate the tooth from the currently engaged hole among the extender position-securing holes (111), and by either retracting or extending the length-adjustable wire roll extender to a different position.

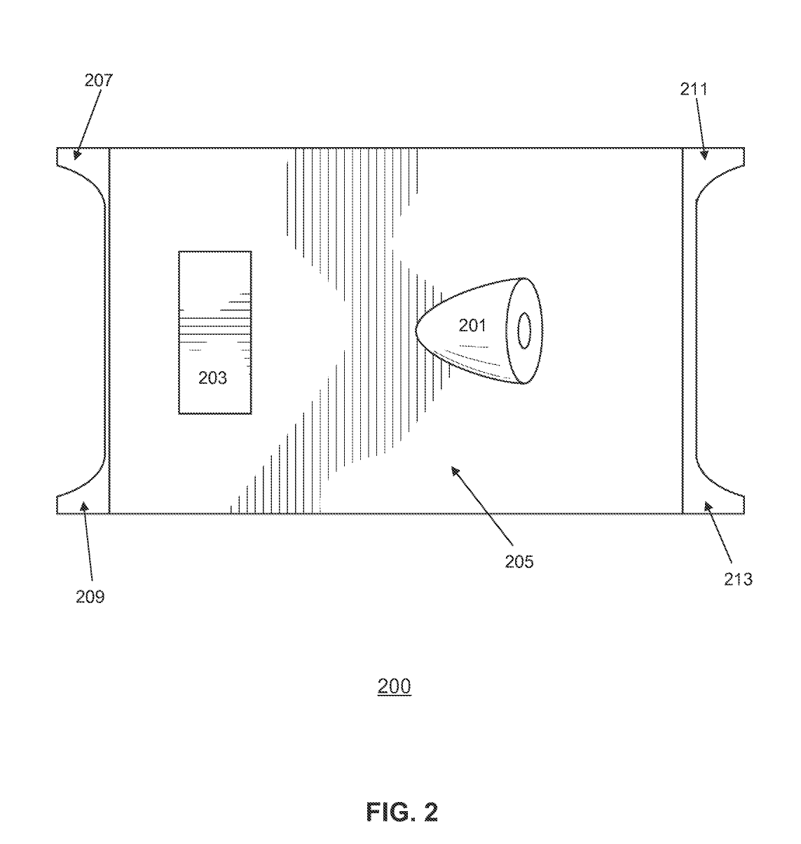

FIG. 2 shows a top view (200) of a mobile device headset interface module (205) with a mute button (203) and an upward-slope headset input port (201) on a top surface of the mobile device headset interface module (205), in accordance with an embodiment of the invention. In this embodiment of the invention, the mobile device headset interface module (205) also has a first roll-slip edge guard comprising a first ridge (207) and a second ridge (209), and a second roll-slip edge guard comprising a third ridge (211) and a fourth ridge (213).

In the embodiment of the invention as shown in FIG. 2, the mute button (203) is capable of blocking or muting sound signals that originate from a sound output port of a mobile device (e.g. 101 of FIG. 1), so that a headset unit (e.g. 117 of FIG. 1) connected to the mobile device headset interface module (205) does not receive any sound through speakers in the headset unit. In one embodiment of the invention, the mute button (203) may physically block or mute the sound transmission to the headset unit (e.g. 117 of FIG. 1). In another embodiment of the invention, the activation of the mute button (203) may trigger a software-based mute command function in a device software operating in the mobile device (e.g. 101 of FIG. 1). Alternatively, the mute button (203) can be utilized to mute or deactivate a microphone that may be embedded in the headset unit or in the mobile device headset interface module (205), so that a user on a telephone call does not transmit any sound through the microphone as long as the mute button (203) is activated. Preferably, by pressing the mute button (203) again, the user can also deactivate the mute feature, whether the mute feature was initially activated to mute sound signals from the sound output port of the mobile device, or initially activated to mute the microphone in the headset unit or in the mobile device headset interface module (205).

Continuing with FIG. 2, the upward-slope headset input port (201) is located on the top surface of the mobile device headset interface module (205) in this embodiment of the invention. The upward-slope headset input port (205) has a uniquely-slanted upward angle for docking with a headset input jack (e.g. 109 of FIG. 1), which reduces chances of impact-related damages to the headset input jack and the mobile device headset interface module (205). In particular, the uniquely-slanted upward angle of the upward-slope headset input port (201) on the top surface of the mobile device headset interface module (205) can substantially reduce impact energy transmitted to the headset input jack and the upward-slope headset input port (201) if these devices experience significant physical shock or impact by a user's accidental mishandling of the mobile device, the mobile device headset interface module (205), and/or the headset unit.

Furthermore, as also shown in FIG. 2, the first roll-slip edge guard comprising the first ridge (207) and the second ridge (209), and the second roll-slip edge guard comprising the third ridge (211) and the fourth ridge (213) are located at opposite edges of the mobile device headset interface module (205). In one embodiment of the invention, the opposite edges may be along the width of the mobile device headset interface module (205), as shown in FIG. 2. In another embodiment of the invention, the opposite edges may be along the length of the mobile device headset interface module (205).

In the embodiment of the invention as shown in FIG. 2, each edge endpoint at each corner of each edge, has a ridge (207, 209, 211, or 213) that forms an elevated wall to prevent slippage of an electrical wire, if the electrical wire is rolled around outer surfaces of the mobile device headset interface module (205). The first roll-slip edge guard forms a U-shaped structure with the first ridge (207) on one edge endpoint and the second ridge (209) on the other edge endpoint. Similarly, the second roll-slip edge guard forms another U-shaped structure with the third ridge (211) on one edge endpoint and the fourth ridge (213) on the other edge endpoint. These U-shaped structures formed by the plurality of ridges (e.g. 207, 209, 211, and 213) prevent a rolled electrical wire from slipping away from the mobile device headset interface module (205), as shown more clearly in FIG. 3 and FIG. 4.

FIG. 3 shows a perspective view (300) of a mobile device headset interface module (303) with a length-adjustable wire roll extender (309) and extender position-securing holes (301), in accordance with an embodiment of the invention. As shown in FIG. 3, the first roll-slip edge guard (305) and the second roll-slip edge guard (307) are located at opposite edges of the mobile device headset interface module (303). In one embodiment of the invention, the opposite edges may be along the width of the mobile device headset interface module (303), as shown in FIG. 3. In another embodiment of the invention, the opposite edges may be along the length of the mobile device headset interface module (303).

In a preferred embodiment of the invention, each edge endpoint is at each corner of each edge, and has a ridge that forms an elevated wall to prevent slippage of a rolled electrical wire (311), which is rolled around outer surfaces of the mobile device headset interface module (303). Preferably, each of the first roll-slip edge guard (305) and the second roll-slip edge guard (307) forms a U-shaped structure with a first ridge on one edge endpoint and a second ridge on the other edge endpoint. The ridge prevents the rolled electrical wire (311) from slipping away from the mobile device headset interface module (303), as shown in FIG. 3.

In the embodiment of the invention as shown in FIG. 3, the mobile device headset interface module (303) also has a unique length-adjustable wire roll extender (309) that can extend from or retracts to an edge of the mobile device headset interface module (303). In one example, the length-adjustable wire roll extender can slide in and out of the edge of the mobile device headset interface module, and attach the second roll-slip edge guard (307) at its exposed edge. Furthermore, this length-adjustable wire roll extender (309) can be used to control or adjust roll termination point for earbuds or headphones as the electrical wire that connects between the mobile device headset interface module (303) and the headset unit (e.g. 117 of FIG. 1) is rolled around a length axis of the mobile device headset interface module (303). For example, if the earbuds terminate its multi-loop roll at an awkward position after the electrical wire that connects the headset unit and the mobile device headset interface module (303) is rolled around the length axis of the mobile device headset interface module (303), then the user may want to extend the length of the mobile device headset interface module (303) by a few inches to ensure that the roll termination point for the earbuds is within the range of a headset-securing clip (e.g. 409 of FIG. 4). The range of extendable movement (313) for the length-adjustable wire roll extender (309) is illustrated in FIG. 3.

Furthermore, as shown in FIG. 3, in one embodiment of the invention, an extended position of the length-adjustable wire roll extender (309) can be securely fixed by using a tooth from a side of the length-adjustable wire roll extender (309), wherein the tooth is configured to snap into one of the extender position-securing holes (301). The user can change or adjust the extended position by pressing the tooth to dislocate the tooth from the currently engaged hole among the extender position-securing holes (301), and by either retracting or extending the length-adjustable wire roll extender (309) to a different position along the range of extendable movement (313).

FIG. 4 shows a perspective view (400) of a mobile device headset interface module (403) with a length-adjustable wire roll extender, extender position-securing holes (401), and a headset-securing clip (409), in accordance with an embodiment of the invention. As shown in FIG. 4, the first roll-slip edge guard (405) and the second roll-slip edge guard (407) are located at opposite edges of the mobile device headset interface module (403). In one embodiment of the invention, the opposite edges may be along the width of the mobile device headset interface module (403), as shown in FIG. 4. In another embodiment of the invention, the opposite edges may be along the length of the mobile device headset interface module (403).

In a preferred embodiment of the invention, each edge endpoint is at each corner of each edge, and has a ridge that forms an elevated wall to prevent slippage of a rolled electrical wire (415), which is rolled around outer surfaces of the mobile device headset interface module (403). In the embodiment of the invention as shown in FIG. 4, the rolled electrical wire (415) connects the mobile device headset interface module (403) and the headset unit (411). In another embodiment of the invention, a different rolled electrical wire may connect the mobile device headset interface module (403) and a mobile device via a module connection jack (413) to the mobile device. Preferably, each of the first roll-slip edge guard (405) and the second roll-slip edge guard (407) forms a U-shaped structure with a first ridge on one edge endpoint and a second ridge on the other edge endpoint. The ridge prevents the rolled electrical wire (415) from slipping away from the mobile device headset interface module (403), as shown in FIG. 4.

In the embodiment of the invention as shown in FIG. 4, the mobile device headset interface module (403) also has a unique length-adjustable wire roll extender that can extend from or retracts to an edge of the mobile device headset interface module (403). In one example, the length-adjustable wire roll extender can slide in and out of the edge of the mobile device headset interface module (403), and attach the second roll-slip edge guard (407) at its exposed edge. Furthermore, this length-adjustable wire roll extender can be used to control or adjust roll termination point for earbuds or headphones as the electrical wire that connects between the mobile device headset interface module (403) and the headset unit (411) is rolled around a length axis of the mobile device headset interface module (403). For example, if the earbuds terminate its multi-loop roll at an awkward position after the electrical wire that connects the headset unit and the mobile device headset interface module (403) is rolled around the length axis of the mobile device headset interface module (403), then the user may want to extend the length of the mobile device headset interface module (403) by a few inches to ensure that the roll termination point for the earbuds is within the range of a headset-securing clip (409).

In one embodiment of the invention, the headset-securing clip (409) contains a spring-loaded crocodile clip element, which is able to securely hold the headset unit (411) by restraining the movement of a remaining tip of the rolled electrical wire (415) with the spring-loaded crocodile clip element pressing against the remaining tip of the rolled electrical wire (415), as shown in FIG. 4. Furthermore, as shown in FIG. 4, in one embodiment of the invention, an extended position of the length-adjustable wire roll extender can be securely fixed by using a tooth from a side of the length-adjustable wire roll extender, wherein the tooth is configured to snap into one of the extender position-securing holes (401). The user can change or adjust the extended position by pressing the tooth to dislocate the tooth from the currently engaged hole among the extender position-securing holes (401), and by either retracting or extending the length-adjustable wire roll extender to a different position.

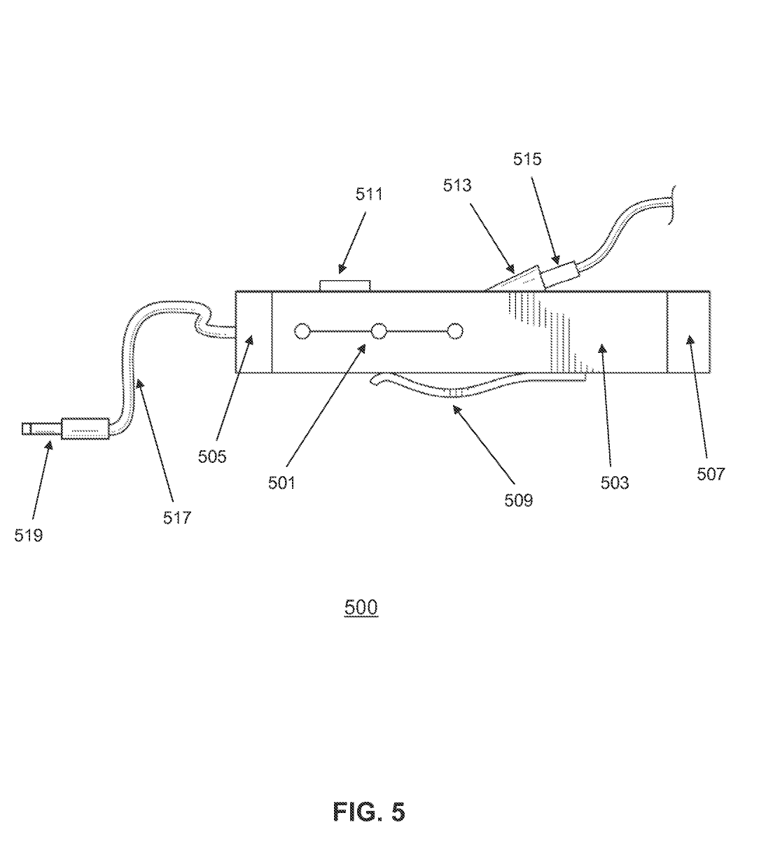

FIG. 5 shows a side view (500) of a mobile device headset interface module (503) with a length-adjustable wire roll extender, extender position-securing holes (501), and a headset-securing clip (509), in accordance with an embodiment of the invention. As shown in FIG. 5, the first roll-slip edge guard (505) and the second roll-slip edge guard (507) are located at opposite edges of the mobile device headset interface module (503). In one embodiment of the invention, the opposite edges may be along the width of the mobile device headset interface module (503), as shown in FIG. 5. In another embodiment of the invention, the opposite edges may be along the length of the mobile device headset interface module (503).

As shown in FIG. 5, in one embodiment of the invention, the mute button (511) is capable of blocking or muting sound signals that originate from a sound output port of a mobile device, so that a headset unit connected to the mobile device headset interface module (503) does not receive any sound through speakers in the headset unit. In one embodiment of the invention, the mute button (511) may physically block or mute the sound transmission to the headset unit. In another embodiment of the invention, the activation of the mute button (511) may trigger a software-based mute command function in a device software operating in the mobile device. Alternatively, the mute button (505) can be utilized to mute or deactivate a microphone that may be embedded in the headset unit or in the mobile device headset interface module (503), so that a user on a telephone call does not transmit any sound through the microphone as long as the mute button (505) is activated. Preferably, by pressing the mute button (505) again, the user can also deactivate the mute feature, whether the mute feature was initially activated to mute sound signals from the sound output port of the mobile device, or initially activated to mute the microphone in the headset unit or in the mobile device headset interface module (503).

Continuing with FIG. 5, the upward-slope headset input port (513) is located on the top surface of the mobile device headset interface module (503) in this embodiment of the invention. The upward-slope headset input port (513) has a uniquely-slanted upward angle for docking with a headset input jack (515), which reduces chances of impact-related damages to the headset input jack (515) and the mobile device headset interface module (503). For example, a conventional headset input port forms a perpendicular angle when it is docking with a typical headset input jack of a typical headset unit. If a user drops or persistently brushes the headset input jack against another solid object while the headset input jack is perpendicularly plugged into the conventional headset input port, the perpendicularity of the headset input jack to the conventional headset input port often amplifies or exacerbates impact or stress energy to the headset input jack and the conventional headset input port, thereby causing substantial damages, undesirable electrical disconnection, or operational malfunctions to these devices. In contrast, in the embodiment of the invention as shown in FIG. 5, the uniquely-slanted upward angle of the upward-slope headset input port (513) on the top surface of the mobile device headset interface module (503) can substantially reduce impact and stress energy transmitted to the headset input jack (515) and the upward-slope headset input port (513) if these devices experience significant physical shock, impact, or stress by a user's accidental mishandling of the mobile device, the mobile device headset interface module (503), and/or the headset unit.

Furthermore, in the embodiment of the invention as shown in FIG. 5, the mobile device headset interface module (503) also has a unique length-adjustable wire roll extender that can extend from or retracts to an edge of the mobile device headset interface module (503). In one example, the length-adjustable wire roll extender can slide in and out of the edge of the mobile device headset interface module (503), and attach the second roll-slip edge guard (507) at its exposed edge. Furthermore, this length-adjustable wire roll extender can be used to control or adjust roll termination point for earbuds or headphones as the electrical wire that connects between the mobile device headset interface module (503) and the headset unit is rolled around a length axis of the mobile device headset interface module (503). For example, if the earbuds terminate its multi-loop roll at an awkward position after the electrical wire that connects the headset unit and the mobile device headset interface module (503) is rolled around the length axis of the mobile device headset interface module (503), then the user may want to extend the length of the mobile device headset interface module (503) by a few inches to ensure that the roll termination point for the earbuds is within the range of a headset-securing clip (509).

Moreover, in one embodiment of the invention, the headset-securing clip (509) contains a spring-loaded crocodile clip element, which is able to securely hold the headset unit by restraining the movement of a remaining tip of the rolled electrical wire with the spring-loaded crocodile clip element pressing against the remaining tip of the rolled electrical wire, as previously shown in FIG. 4. In addition, in one embodiment of the invention, an extended position of the length-adjustable wire roll extender can be securely fixed by using a tooth from a side of the length-adjustable wire roll extender, wherein the tooth is configured to snap into one of the extender position-securing holes (501). The user can change or adjust the extended position by pressing the tooth to dislocate the tooth from the currently engaged hole among the extender position-securing holes (501), and by either retracting or extending the length-adjustable wire roll extender to a different position.

In one embodiment of the invention, the mobile device headset interface module (503) also includes an electrical wire (517) to a mobile device, and a module connection jack (519) to the mobile device, as shown in FIG. 5. The module connection jack (519) is configured to receive sound signals or other electrical signals, which are either utilized in the mobile device headset interface module (503) or in the headset unit operatively connected to the mobile device via the mobile device headset interface module (503). Preferably, the mobile device headset interface module (503) is configured to provide sound volume control functions and sound mute functions, while also enabling a generic (i.e. not manufacturer-specific) headset input jack (e.g. 515) to work with a mobile device that has a manufacturer-specific audio output port, which limits the user's choice of using a variety of headset units in conjunction with the mobile device.

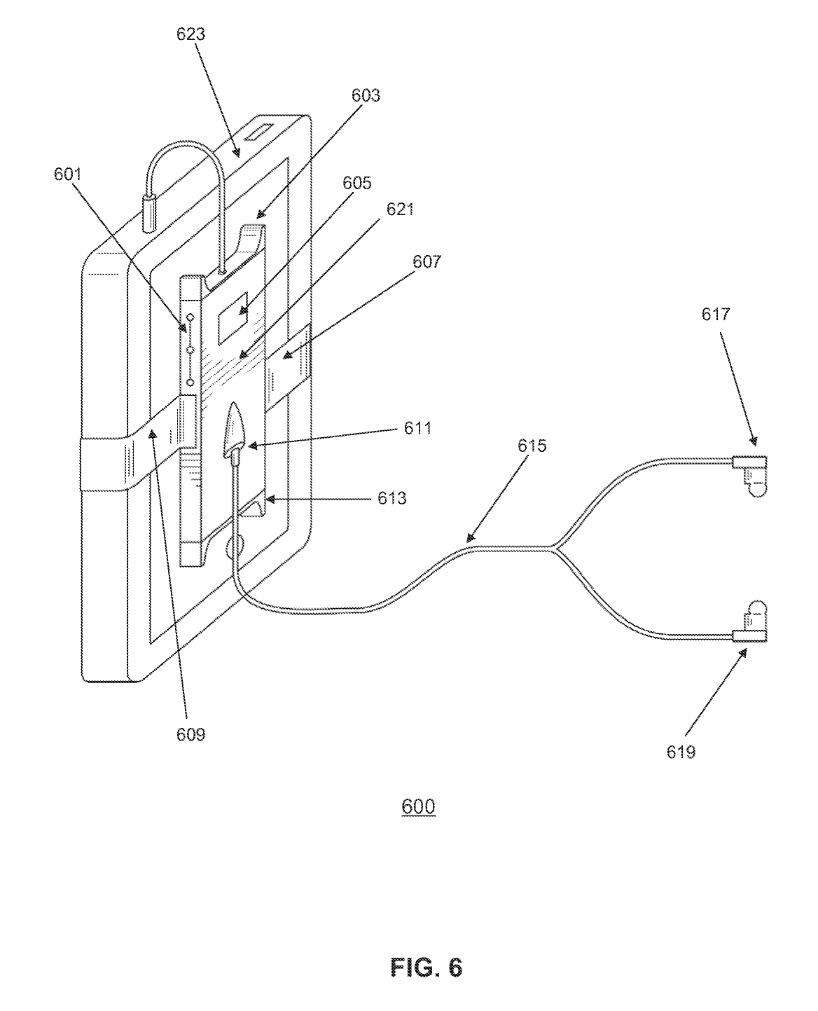

FIG. 6 shows a perspective view (600) of a mobile device headset interface module (621) attached to a body of a mobile device (623) using detachable belt straps (607, 609), in accordance with an embodiment of the invention. In this embodiment of the invention, the mobile device headset interface module (621) has the detachable belt straps (607, 609) on its outer surface, so that the mobile device headset interface module (621) can be strapped onto the mobile device (623) if a user desires to do so, as shown in FIG. 6. In addition, the detachable belt straps (607, 609) may include Velcro strips, a clasp, or another strap closure element which can be used to securely attach the mobile device headset interface module (621) to the mobile device (623).

In an alternate embodiment of the invention, instead of using the detachable belt straps (607, 609) as shown in FIG. 6, the mobile device headset interface module (621) may utilize nano suctions or air suctions on a surface of the mobile device headset interface module (621) to achieve detachable attachment of the mobile device headset interface module (621) to the main body of the mobile device (623). For example, a rear surface of the mobile device headset interface module (621) may incorporate a layer of nano suctions, which enable detachable attachment of the mobile device headset interface module (621) to the main body of the mobile device (623).

Furthermore, in one embodiment of the invention, the mobile device headset interface module (621) also includes a mute button (605), an upward-slope headset input port (611), roll-slip edge guards (603, 613), and extender position-securing holes (601). Moreover, an electrical wire (615) with a headset input jack plugged into the upward-slope headset input port (611) is operatively and electrically connected to a headset unit (617, 619), which may be a pair of earbuds as illustrated, or a headphone unit in another embodiment of the invention.

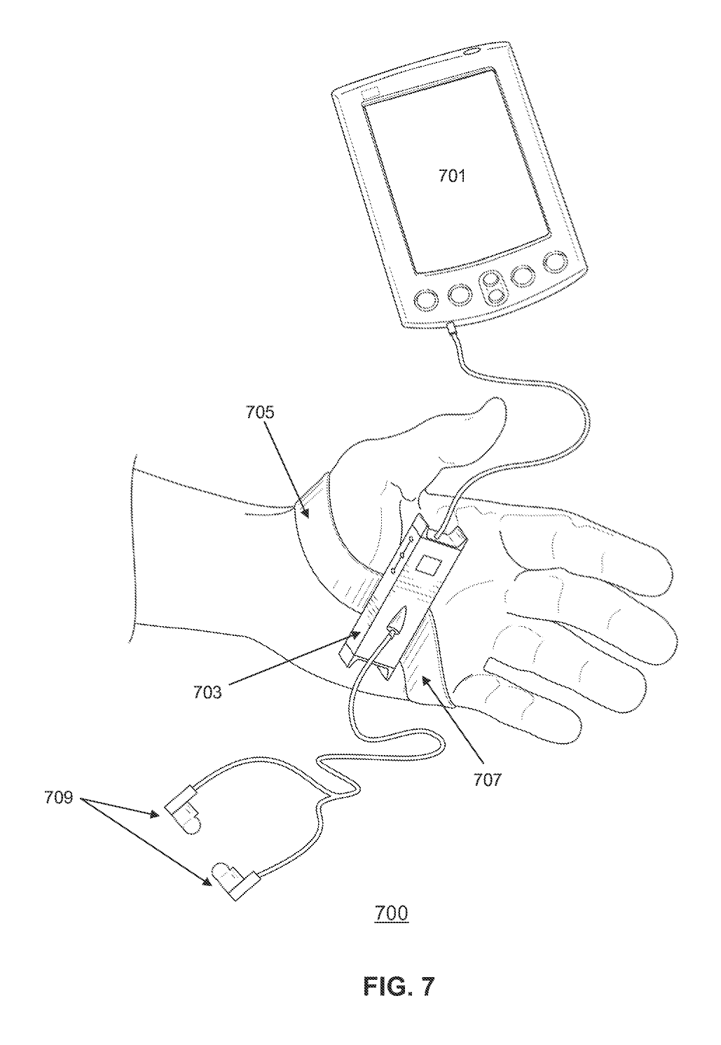

FIG. 7 show a perspective view (700) of a mobile device headset interface module (703) attached to a user's hand using detachable belt straps (705, 707), in accordance with an embodiment of the invention. In this embodiment of the invention, the mobile device headset interface module (703) has the detachable belt straps (705, 707) on its outer surface, so that the mobile device headset interface module (703) can be strapped onto the user's hand if the user desires to do so. The mobile device headset interface module (703) is operatively and electrically connected to a mobile device (701) and a headset unit (709), and can accommodate sound volume control, mute activation or deactivation, or another desirable feature that can be incorporated into the mobile device headset interface module (703). In addition, the detachable belt straps (705, 707) may include Velcro strips, a clasp, or another strap closure element which can be used to securely attach the mobile device headset interface module (703) to the mobile device (701).

As shown and described above, various embodiments of the present invention disclose novel mobile device headset interface module designs that provide significant advantages. For example, a novel mobile device headset interface module in accordance with an embodiment of the invention can reduce or eliminate tangling of interconnecting electrical wires by utilizing uniquely-configured wire roll-slip edge guards. Furthermore, the novel mobile device headset interface module in accordance with an embodiment of the invention can further reduce or eliminate tangling of interconnecting electrical wires and protect earpieces in the headset unit against damages or electrical disconnections by utilizing a length-adjustable wire roll extender, which is structurally part of the novel mobile device headset interface module.

In addition, the novel mobile device headset interface module can be easily attachable and detachable to a main body of the mobile device. The novel mobile device headset interface module in accordance with an embodiment of the invention can also reduce or eliminate the chances of input jack damages. Furthermore, the novel mobile device headset interface module can incorporate a call and/or sound mute button for additional convenience to the user during operation of a mobile device.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A mobile device headset interface module comprising:
a roll-slip edge guard with one or more ridges at each edge endpoint of the mobile device headset interface module, wherein each ridge forms an elevated wall at each edge endpoint to prevent slippage of an electrical wire that is rolled around outer surfaces of the mobile device headset interface module;
an upward-slope headset input port located on a top surface of the mobile device headset interface module, wherein the upward-slope headset input port is configured to dock with a headset input jack of a headset unit at a non-perpendicular angle, which reduces chances of impact-related damages or undesirable electrical disconnections to the headset input jack and the mobile device headset interface module; and
a mute button located on the top surface of the mobile device headset interface module, wherein the mute button blocks or mutes sound signals originating from a mobile device or from the headset unit, which is operatively connected to the mobile device headset interface module.

2. The mobile device headset interface module of claim 1, further comprising a length-adjustable wire roll extender attached with the roll-slip edge guard, wherein the length-adjustable wire roll extender extends from and retracts to an edge of the mobile device headset interface module.

3. The mobile device headset interface module of claim 2, further comprising extender position-securing holes, wherein a tooth from a side of the length-adjustable wire roll extender securely snaps into one of the extender position-securing holes to keep an extended position of the length-adjustable wire roll extender fixed until a user presses the tooth to change the extended position of the length-adjustable wire roll extender to a different position.

4. The mobile device headset interface module of claim 1, further comprising a headset-securing clip that closely and securely holds a current position of the headset unit when the headset-securing clip is pressing against the electrical wire connected to the headset unit.

5. The mobile device headset interface module of claim 1, further comprising a second electrical wire that physically and electrically connects the mobile device headset interface module to a sound output port of the mobile device.

6. The mobile device headset interface module of claim 1, further comprising one or more detachable belt straps on a surface of the mobile device headset interface module, wherein the one or more detachable belt straps enable secure attachment of the mobile device headset interface module to the mobile device or a user's hand.

7. The mobile device headset interface module of claim 1, further comprising a layer of nano suctions on a surface of the mobile device headset interface module, wherein the layer of nano suctions enables secure attachment of the mobile device headset interface module to the mobile device or a user's hand.

8. The mobile device headset interface module of claim 1, wherein the headset unit is a headphone unit or an earbud unit.

9. The mobile device headset interface module of claim 1, wherein the mobile device is a smart phone, a cellular phone, a tablet computer, a notebook computer, or a portable music player device.

10. A mobile device headset interface module comprising:
a first roll-slip edge guard with a first set of ridges at edge endpoints of a first edge of the mobile device headset interface module;
a second roll-slip edge guard with a second set of ridges at edge endpoints of a second edge of the mobile device headset interface module, wherein each ridge forms an elevated wall at each edge endpoint to prevent slippage of an electrical wire that is rolled around outer surfaces of the mobile device headset interface module, and wherein the first edge and the second edge are opposite to each other;
an upward-slope headset input port located on a top surface of the mobile device headset interface module, wherein the upward-slope headset input port is configured to dock with a headset input jack of a headset unit at a non-perpendicular angle, which reduces chances of impact-related damages or undesirable electrical disconnections to the headset input jack and the mobile device headset interface module; and
a mute button located on the top surface of the mobile device headset interface module, wherein the mute button blocks or mutes sound signals originating from a mobile device or from the headset unit, which is operatively connected to the mobile device headset interface module.

11. The mobile device headset interface module of claim 10, further comprising a length-adjustable wire roll extender attached with the first roll-slip edge guard, wherein the length-adjustable wire roll extender extends from and retracts to the first edge of the mobile device headset interface module.

12. The mobile device headset interface module of claim 11, further comprising extender position-securing holes, wherein a tooth from a side of the length-adjustable wire roll extender securely snaps into one of the extender position-securing holes to keep an extended position of the length-adjustable wire roll extender fixed until a user presses the tooth to change the extended position of the length-adjustable wire roll extender to a different position.

13. The mobile device headset interface module of claim 10, further comprising a headset-securing clip that closely and securely holds a current position of the headset unit when the headset-securing clip is pressing against the electrical wire connected to the headset unit.

14. The mobile device headset interface module of claim 10, further comprising a second electrical wire that physically and electrically connects the mobile device headset interface module to a sound output port of the mobile device.

15. The mobile device headset interface module of claim 10, further comprising one or more detachable belt straps on a surface of the mobile device headset interface module, wherein the one or more detachable belt straps enable secure attachment of the mobile device headset interface module to the mobile device or a user's hand.

16. The mobile device headset interface module of claim 10, further comprising a layer of nano suctions on a surface of the mobile device headset interface module, wherein the layer of nano suctions enables secure attachment of the mobile device headset interface module to the mobile device or a user's hand.

17. The mobile device headset interface module of claim 10, wherein the headset unit is a headphone unit or an earbud unit.

18. The mobile device headset interface module of claim 10, wherein the mobile device is a smart phone, a cellular phone, a tablet computer, a notebook computer, or a portable music player device.
